(19) United States
(12) Patent Application Publication
(10) Pub. No.: US 2012/0174955 A1
(43) Pub. Date: Jul. 12, 2012

(54) THERMOELECTRIC MODULE

(75) Inventors: Youngnam HWANG, Gyeonggi-do (KR); Hyunjik Yang, Gyeonggi-do (KR); Dongik Shin, Gyeonggi-do (KR); Subong Jang, Gyeonggi-do (KR)

(73) Assignee: SAMSUNG Electro-Mechanics Co., Ltd.

(21) Appl. No.: 13/188,263

(22) Filed: Jul. 21, 2011

(30) Foreign Application Priority Data
Jan. 10, 2011 (KR) 10-2011-0002249

(51) Int. Cl. H01L 35/30

(52) U.S. Cl. 136/203

(57) ABSTRACT

Disclosed herein is a thermoelectric module. The thermoelectric module is configured by enlarging a cross-section of a P-type thermoelectric device than that of an N-type thermoelectric device, thereby making it possible to reduce unbalance in heat distribution at a high temperature side or a low temperature side of the thermoelectric module and improve thermoelectric performance.

### CROSS REFERENCE(S) TO RELATED APPLICATIONS

This application claims the benefit under 35 U.S.C. Section 119 of Korean Patent Application Serial No. 10-2011-0002249, entitled “Thermoelectric Module” filed on Jan. 10, 2011, which is hereby incorporated by reference in its entirety into this application.

### BACKGROUND OF THE INVENTION

1. Technical Field

The present invention relates to a thermoelectric module, and more particularly, to a thermoelectric module having improved thermoelectric performance by differentiating a cross-section of a P-type thermoelectric device from that of an N-type thermoelectric device.

2. Description of the Related Art

A thermoelectric phenomenon, which means a reversible direct energy conversion between heat and electricity, is generated due to movement of electrons and holes in a material. The thermoelectric phenomenon may be divided into a Peltier effect that is applied to a cooling field using a temperature difference on both ends formed by a current applied from the outside and a Seebeck effect that is applied to a generating field using electromotive force generated due to a temperature difference on both ends of a material.

A thermoelectric module using such thermoelectric phenomenon may be configured to include thermoelectric devices, metal electrodes connecting the thermoelectric devices, an upper substrate and a lower substrate supporting the thermoelectric devices and the metal electrodes and performing heat-exchange.

Generally, P-type and N-type semiconductors are used as the thermoelectric devices and the module is configured by arranging a pair of P-type thermoelectric device and N-type thermoelectric device, which is formed in plural, on a plane and then connecting them in series using the metal electrodes.

When a DC current is applied to the thermoelectric module configured as described above, electrons (e−) and holes (h+), carriers, are generated from the metal electrode at one side, such that the electrons flow to the N-type thermoelectric device and the holes flow to the P-type thermoelectric device, respectively, while transferring heat, and then, the carriers are recombined at the electrode opposite thereto. Heat-absorption occurs from the electrode in which the carriers are generated and a substrate adjacent thereto and heat-generation occurs from the electrode in which the carriers are recombined and a substrate adjacent thereto, and these portions may each be called a cold side and a hot side, which configure both surfaces of the thermoelectric module.

Meanwhile, thermal conductivity in using the thermoelectric module is one of the most important factors related to thermoelectric performance. Unbalance in heat distribution of the substrate configured of the substrate, the electrodes, and the thermoelectric devices, unbalance in thermal conductivity of the P-type thermoelectric device and the N-type thermoelectric device, or the like may reduce heat-transfer function or the like to the substrate, thereby causing degradation in thermoelectric performance of the module.

In this case, the metal electrodes are formed at top surfaces and bottom surfaces of the thermoelectric devices, in which the P-type thermoelectric devices are bonded to the N-type thermoelectric devices in a π form, and serve to electrically connect the respective thermoelectric devices in series. In the case of the thermoelectric devices provided in the general thermoelectric module according to the related art, the P-type thermoelectric device is formed to have the same cross-section as that of the N-type thermoelectric device.

However, since the amount of heat of the P-type thermoelectric device due to the Peltier effect is larger than that of the N-type thermoelectric device, if the P-type thermoelectric device is formed to have the same or similar cross-section as or to that of the N-type thermoelectric device, it causes thermal unbalance on the substrate.

### SUMMARY OF THE INVENTION

In order to improve thermoelectric performance of a thermoelectric module according to a related art, in which a P-type thermoelectric device and an N-type thermoelectric device are configured to have the same cross-section, without considering a difference in thermoelectric performance of the P-type thermoelectric device and the N-type thermoelectric device, an object of the present invention is to provide a thermoelectric module having improved thermoelectric performance by enlarging a cross-section of a P-type thermoelectric device than that of an N-type thermoelectric device.

According to an exemplary embodiment of the present invention, there is provided a thermoelectric module, including: P-type thermoelectric devices, N-type thermoelectric devices, metal electrodes, an upper substrate, and a lower substrate, wherein a cross-section of the P-type thermoelectric device is different from that of the N-type thermoelectric device.

The cross-section of the P-type thermoelectric device may be formed to be larger than that of the N-type thermoelectric device.

A cross-section ratio R of the P-type thermoelectric device with respect to the N-type thermoelectric device may be determined to be in a range of 1<R≦2.12.

A cross-section of the P-type thermoelectric device may be 1.55 times that of the N-type thermoelectric device.

Meanwhile, the thermoelectric module may further include a bonding part made of a bonding material and formed between the thermoelectric device and the electrode, wherein the bonding part includes a diffusion preventing layer preventing compositions of the electrode or the bonding material from diffusing to the thermoelectric device.

The diffusion preventing layer may be made of nickel or molybdenum.

The diffusion preventing layer may be formed by plating.

The diffusion preventing layer may contact the thermoelectric device to chemically isolate the thermoelectric device from the electrode and the bonding material.

### BRIEF DESCRIPTION OF THE DRAWINGS

FIG. 1 is a partially cutaway perspective view showing a configuration of a general thermoelectric module;

FIG. 2 is a side cross-sectional view showing a configuration of a thermoelectric module provided with a pair of thermoelectric devices in a general thermoelectric module;

FIG. 3 is a side cross-sectional view showing a configuration of a thermoelectric module according to an exemplary embodiment of the present invention; and

FIG. 4 is a graph showing a change in temperature deviation according to a cross-section ratio between a P-type thermoelectric device and an N-type thermoelectric device.

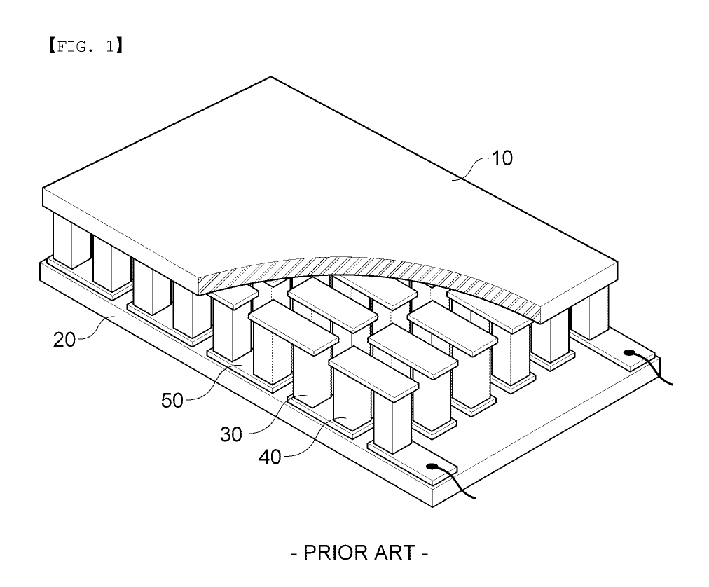

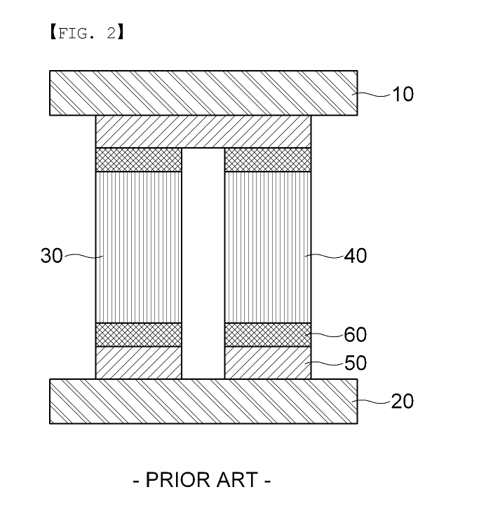

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements 130 but not the exclusion of any other constituents, steps, operations and/or elements 130.

The acting effects and technical configuration with respect to the objects of a thermoelectric module 100 according to the present invention will be clearly understood by the following description in which exemplary embodiments of the present invention are described with reference to the accompanying drawings.

Hereinafter, the configuration and acting effects of a thermoelectric module 100 according to exemplary embodiments of the present invention will be described in more detail with reference to the accompanying drawings.

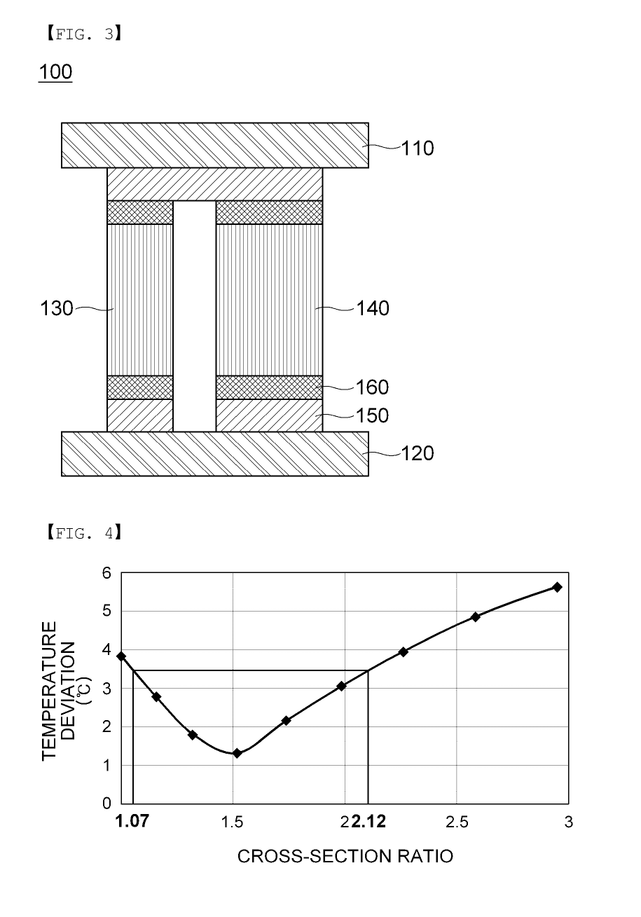

FIG. 3 is a side cross-sectional view showing a configuration of a thermoelectric module 100 according to an exemplary embodiment of the present invention.

Referring to FIG. 3, the thermoelectric module 100 according to an exemplary embodiment of the present invention may be configured to include an N-type thermoelectric device 130, a P-type thermoelectric device 140, electrodes 150, and substrates, in the same manner as another general thermoelectric module 100.

Meanwhile, performance of the thermoelectric device is determined by dimensionless figure of merit ZT, defined by the following Equation 1.

$$ZT = \frac{{S}^{2} σ T}{k} \qquad [ Equation 1 ]$$

S: Seebeck coefficient

σ: Electric conductivity

T: Absolute temperature

K: Thermal conductivity

As the dimensionless figure of merit ZT becomes larger, the characteristics of thermoelectric performance become better. Therefore, the thermoelectric device may be configured of a material having high Seebeck coefficient and electric conductivity and having low thermal conductivity, wherein in the case of the Seebeck coefficient, a unique physical value of the material that is given as a function of temperature, the P-type thermoelectric device 140 generally has higher dimensionless figure of merit ZT than the N-type thermoelectric device 130.

When a DC voltage is applied to the metal electrodes 150 through a lead line, a substrate side in which current flows from the N-type thermoelectric device 130 to the P-type thermoelectric device 140 due to the Peltier effect absorbs heat to act as a cold side and a substrate side in which current flows from the P-type thermoelectric device 140 to the N-type thermoelectric device 130 is heated to act as a hot side. Therefore, in view of a module unit, the cooling effect of the thermoelectric module 100 may be considered to be improved when temperature distribution on the surface of the substrate acting as the cold side is uniformly formed at a low temperature.

However, when the thermoelectric module 100 is configured using the P-type thermoelectric device 140 and the N-type thermoelectric device 130 each having the same cross-section, the thermal unbalance according to a difference in the thermal performance of the P-type thermoelectric device 140 and the N-type thermoelectric device 130 is not considered to generate deviation in temperature distribution on the surface of the substrate acting as the cold side, such that the cooling effect is degraded.

Meanwhile, it may be appreciated that the amount of heat of the thermoelectric module 100 is obtained by subtracting the amount of heat due to thermal conductivity from the amount of heat due to the Peltier effect. However, the amount of heat of the P-type thermoelectric device 140 due to the Peltier effect is larger than that of the N-type thermoelectric device 130 due to the Peltier effect.

In addition, the amounts of heat of the P-type thermoelectric device 140 and the N-type thermoelectric device 130, each having the same cross-section, due to thermal conductivity are the same or similar to each other.

Therefore, the total amount of heat transferred in the thermoelectric module 100 is formed to be different per the P-type thermoelectric device 140 region and the N-type thermoelectric device 130 region, thereby causing unbalance in heat distribution of the substrate.

Considering the above, in the thermoelectric module 100 according to the exemplary embodiment of the present invention, the cross-section of the P-type thermoelectric device 140 is formed to be larger than that of the N-type thermoelectric device 130 to be bonded between the substrate and the electrode 150.

Meanwhile, FIG. 3 shows a case in which a bonding part 160 is provided so as to form a bond between the thermoelectric device and the electrode 150, wherein the bonding part 160 may be made by soldering or the like.

In addition, the bonding part 160 may be configured to include a diffusion preventing layer preventing compositions of the electrode 150 or a bonding material from diffusing to the thermoelectric device.

Furthermore, the bonding part 160 may be configured to include the diffusion preventing layer preventing thermoelectric performance from being degraded as compositions of a solder or the electrode 150 are diffused to the thermoelectric device.

In this case, the diffusion preventing layer may be made of nickel or molybdenum so as to maintain purity of the thermoelectric device and may also be formed by plating or the like.

The diffusion preventing layer as described above may contact the thermoelectric device to chemically isolate the electrode 150 and the bonding material from the thermoelectric device.

FIG. 4 is a graph showing a change in temperature deviation according to a cross-section ratio between a P-type thermoelectric device 140 and an N-type thermoelectric device 130.

Referring to FIG. 4, it is appreciated that when a cross-section ratio R between the P-type thermoelectric device 140 and the N-type thermoelectric device 130 is 1, a temperature deviation in the entire region of substrate is about 4° C. as a result of the measurement thereof.

At this time, if R is increased, the temperature deviation is decreased. This phenomenon occurs as the unbalance due to the device characteristics of the N-type thermoelectric device and the P-type thermoelectric device becomes small. When R is about 1.55, the unbalance due to the device characteristics is minimized, thereby making it possible to accomplish a minimum temperature deviation.

Meanwhile, when R exceeds 1.55, the temperature deviation is increased again, and when R exceeds 2.12, the temperature deviation becomes the same as that in the case in which R is 1 and then the temperature deviation becomes larger according to an increase of R. Such phenomenon occurs since a thermoelectric process is performed, while characteristics of each component of the thermoelectric module, such as physical property, size, shape, and the like, are interacting with each other.

In other words, the unbalance of the device characteristics between the N-type and the P-type thermoelectric devices may be solved by differentiating the cross-section ratio of the thermoelectric devices; however, when the cross-section ratio of the thermoelectric device becomes larger than a predetermined value, the unbalance is again exhibited, and as a result, the temperature deviation of the thermoelectric module is further deteriorated.

As shown in FIG. 4, the temperature deviation is reduced in a range of 1<R≦2.12 as compared to a general case, such that the cross-section ratio R of the P-type thermoelectric device 140 with respect to the N-type thermoelectric device 130 may be determined to be within a range of 1<R≦2.12.

Meanwhile, a reduced width in the temperature deviation is maximized when the cross-section of the P-type thermoelectric device 140 is 1.55 times the cross-section of the N-type thermoelectric device 130, such that R may preferably be 1.55.

According to the exemplary embodiments of the present invention, the cross-section of the P-type thermoelectric device is formed to be larger than that of the N-type thermoelectric device by considering a difference in the thermoelectric performance between the P-type thermoelectric device and the N-type thermoelectric device, thereby making it possible to solve unbalance in heat distribution at the high temperature side or the low temperature side of the thermoelectric module.

In addition, the unbalance in the heat distribution at the high temperature side or the low temperature side is solved, thereby making it possible to further improve the thermoelectric performance of the thermoelectric module as compared to the thermoelectric module according to the related art.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A thermoelectric module, comprising:
P-type thermoelectric devices,
N-type thermoelectric devices,
metal electrodes,
an upper substrate, and
a lower substrate,
wherein a cross-section of the P-type thermoelectric device is different from that of the N-type thermoelectric device.

2. The thermoelectric module according to claim 1, wherein the cross-section of the P-type thermoelectric device is formed to be larger than that of the N-type thermoelectric device.

3. The thermoelectric module according to claim 1, wherein a cross-section ratio R of the P-type thermoelectric device with respect to the N-type thermoelectric device is in a range of 1<R≦2.12.

4. The thermoelectric module according to claim 1, wherein the cross-section of the P-type thermoelectric device is 1.55 times that of the N-type thermoelectric device.

5. The thermoelectric module according to any one of claims 1 to 4, further comprising a bonding part made of a bonding material and formed between the thermoelectric device and the electrode,
wherein the bonding part includes a diffusion preventing layer preventing compositions of the electrode or the bonding material from diffusing to the thermoelectric device.

6. The thermoelectric module according to claim 5, wherein the diffusion preventing layer is made of nickel or molybdenum.

7. The thermoelectric module according to claim 5, wherein the diffusion preventing layer is formed by plating.

8. The thermoelectric module according to claim 5, wherein the diffusion preventing layer contacts the thermoelectric device to chemically isolate the thermoelectric device from the electrode and the bonding material.
